(19) United States
(12) Patent Application Publication
(10) Pub. No.: US 2010/0102405 A1
(43) Pub. Date: Apr. 29, 2010

(54) ST-RAM EMPLOYING A SPIN FILTER

(75) Inventor: Xiaohua Lou, Bloomington, MN (US)

Correspondence Address: CAMPBELL NELSON WHIPPS, LLC, HISTORIC HAMM BUILDING, 408 SAINT PETER STREET, SUITE 240, ST. PAUL, MN, 55102, US

(73) Assignee: SEAGATE TECHNOLOGY LLC, Scotts Valley, CA (US)

(21) Appl. No.: 12/258,492

(22) Filed: Oct. 27, 2008

(51) Int. Cl. H01L 43/10

(52) U.S. Cl. 257/421; 257/204; 257/E43.005

(57) ABSTRACT

A memory cell that includes a first electrode layer; a spin filter layer that includes a material that has exchange splitting in the conduction band; and a magnetic layer, wherein the magnetization of the second magnetic layer can be effected by the torque of electrons tunneling through, wherein the spin filter layer is between the first electrode layer and the magnetic layer.

### BACKGROUND

New types of memory have demonstrated significant potential to compete with commonly utilized forms of memory. For example, non-volatile spin-transfer torque random access memory (referred to herein as “ST-RAM”) has been discussed as a “universal” memory. Techniques, designs and modifications designed to improve currently utilized structures and materials remain an important area of advancement to maximize the advantages of ST-RAM.

### BRIEF SUMMARY

Disclosed herein is a memory cell that includes a first electrode layer; a spin filter layer that includes a material that has exchange splitting in the conduction band; and a magnetic layer, wherein the magnetization orientation of the magnetic layer can be effected by the torque of electrons tunneling through, wherein the spin filter layer is between the first electrode layer and the magnetic layer.

Additional embodiments disclose a memory array that includes a plurality of memory structures, each of the plurality of memory structures comprising a memory cell, wherein the memory cell includes a first electrode layer; a spin filter layer that includes a material that has exchange splitting in the conduction band; and a magnetic layer, wherein a magnetization orientation of the magnetic layer can be effected by the torque of electrons tunneling through, wherein the spin filter layer is between the first electrode layer and the magnetic layer; and a transistor, wherein the transistor is operatively coupled to the memory cell; a plurality of bit lines; and a plurality of source lines, wherein each of the plurality of memory cells is operatively coupled between a bit line and a source line, the plurality of memory cells are arranged in a matrix and the bit lines and source lines connect the plurality of memory cells; and a plurality of word lines; wherein each of the plurality of transistors are operatively coupled to a word line.

### BRIEF DESCRIPTION OF THE DRAWINGS

The disclosure may be more completely understood in consideration of the following detailed description of various embodiments of the disclosure in connection with the accompanying drawings, in which:

FIG. 1 is an illustration of a memory cell;

FIG. 2 is an illustration of a memory cell that includes a GMR spin valve forming structure;

FIG. 3 is an illustration of a GMR spin valve forming structure;

FIG. 4 is an illustration of a memory cell that includes a GMR spin valve forming structure;

FIGS. 5a and 5b are schematic circuit diagrams of a memory device;

FIG. 6 is an illustration of a memory device containing a memory cell as disclosed herein; and

FIG. 7 is a schematic circuit diagram of an illustrative memory array.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

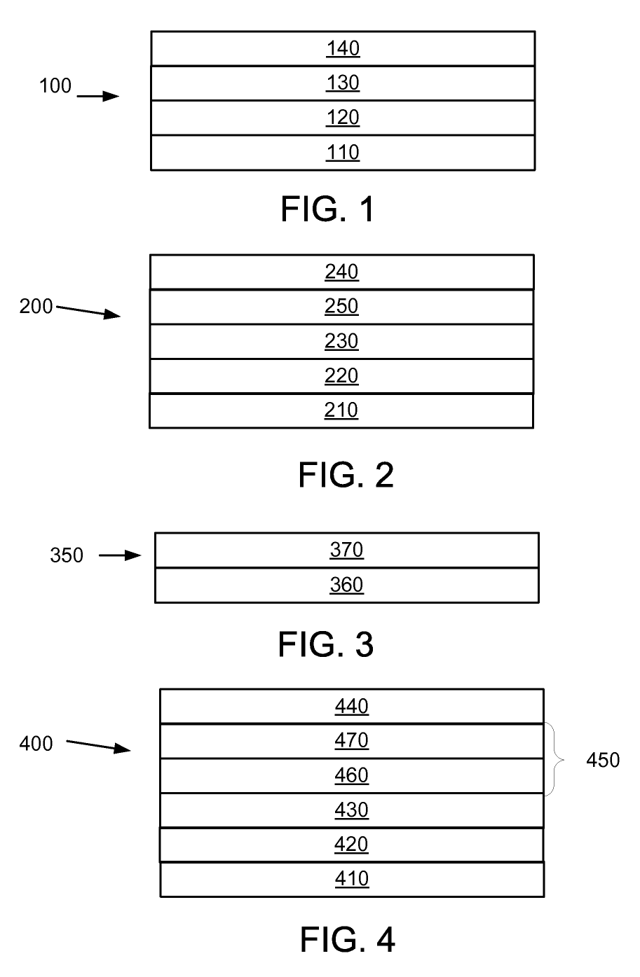

An embodiment of a memory cell as disclosed herein includes a non-magnetic layer and a spin filter layer, wherein the spin filter layer is situated on the non-magnetic layer. An embodiment of a memory cell 100 as disclosed herein is illustrated in FIG. 1, includes a first electrode layer 110, a spin filter layer 120, a magnetic layer 130, and optionally a second electrode layer 140.

The spin filter layer 120 generally includes a material that has exchange splitting in the conduction band. A spin filter material generally functions to have a barrier height for spin-up and spin-down electrons that are different. This effects a difference in magnitude of tunneling currents for spin-up and spin-down electrons. When utilized in a ST-RAM configuration, a spin filter material functions as a pinned magnetic layer and a tunnel barrier. For this reason, a memory cell that utilizes a spin filter material in place of a pinned magnetic layer and a tunnel barrier can provide advantages. Conventional ST-RAM cells can include an antiferromagnetic layer, a synthetic antiferromagnetic coupled pinned layer and a reference layer to provide magnetic stability. These multiple magnetic layers make conventional ST-RAM structures complicated and can lead to magnetism related problems that can destroy the device yield and switching uniformity. In contrast to that, memory cells as disclosed herein can function properly with only a non-magnetic electrode under the spin filter material; this structure is much simpler and can be immune to magnetism related problems that can be observed in conventional ST-RAM cells, such as magnetic static coupling.

In an embodiment, the spin filter layer 120 can include any material that has exchange splitting in the conduction band. Exemplary materials that can be utilized include, but are not limited to, materials that include europium (Eu), selenium (Se), cobalt (Co), iron (Fe), bismuth (Bi), manganese (Mn), nickel (Ni) or combinations thereof. In an embodiment, the spin filter material can include EuS, EuO, EuSe, CoFe₂O₄, BiMnO₃, or NiFe₂O₄.

In an embodiment, the spin filter layer has a thickness in the range of about 2 nanometers (nm) to about 10 nm.

The magnetic layer 130 can be made of commonly utilized ferromagnetic materials. For example, ferromagnetic alloys such as iron (Fe), cobalt (Co), and nickel (Ni) alloys can be utilized. In an embodiment, the magnetic layer 130 can be made of alloys such as FeMn, NiO, IrMn, PtPdMn, NiMn and TbCo for example. In an embodiment, the magnetic layer 130 can have a thickness in the range of about 1 nm to about 5 nm.

A memory cell as disclosed herein can also include a first electrode layer 110. The first electrode layer 110 generally functions to electrically connect the memory cell to control circuitry. The first electrode layer 110 can generally have a thickness in the range of about 10 nm to about 1 micron. In an embodiment, the first electrode layer 110 can be made of materials that are commonly utilized for electrode layers within memory cells, including, but not limited to tungsten (W) and titanium nitride (TiN).

A memory cell as disclosed herein can also include a second electrode layer 140 in one embodiment. The second electrode layer 140 generally functions to electrically connect the memory cell to control circuitry. The second electrode layer 140 can generally have a thickness from about 10 nm to about 1 micron. In an embodiment, the second electrode layer 140 can be made of materials that are commonly utilized for electrode layers within memory cells, including, but not limited to tungsten (W) and titanium nitride (TiN).

The first electrode layer 110 and the second electrode layer 140 electrically connect the spin filter layer 120 and the magnetic layer 130 respectively to a control circuit (not shown) that provides read and write currents through the layers. When a current is driven across the memory cell, the spin filter layer will have different barriers for spin-up and spin-down electrons. When writing to the magnetic layer 130, the spin filter layer 120 behaves like the combination of the reference layer and the tunneling barrier, therefore injecting currents into the structure can switch the magnetization vector of the magnetic layer back and forth depending on current direction. When reading from the magnetic layer 130, the resistance to current across the structure will be due to the orientation of the magnetization vector of the magnetic layer 130.

FIG. 2 provides another exemplary embodiment that includes a first electrode layer 210, a spin filter layer 220, a magnetic layer 230, a giant magnetoresistive (GMR) spin valve forming structure 250 and a second electrode 240. A GMR spin valve generally exhibits changes in electrical resistance in the presence or absence of magnetization vectors. Generally, a GMR spin valve has two magnetic layers separated by a non-magnetic spacer layer.

An exemplary structure of a GMR spin valve forming structure is illustrated in FIG. 3. A GMR spin valve forming structure 350 can generally include a GMR nonmagnetic layer 360 and a GMR magnetic layer 370. The GMR spin valve forming structure 350, when combined with the magnetic layer 130 of the memory cell affords the functionality of a GMR spin valve.

The GMR nonmagnetic layer 360 of a GMR spin valve forming structure 350 can include any nonferromagnetic material. Exemplary materials include, but are not limited to chromium (Cr), copper (Cu), and aluminum (Al). In an embodiment, a GMR nonmagnetic layer 360 can have a thickness in the range of about 1 nm to about 50 nm. In an embodiment, a GMR nonmagnetic layer 360 can have a thickness in the range of about 10 nm to about 50 nm.

The GMR magnetic layer 370 of a GMR spin valve forming structure 350 can include any commonly utilized ferromagnetic materials. For example, ferromagnetic alloys such as iron (Fe), cobalt (Co), and nickel (Ni) alloys can be utilized. In an embodiment, the GMR magnetic layer 370 can be made of alloys such as FeMn, NiO, IrMn, PtPdMn, NiMn and TbCo for example, in an embodiment, the GMR magnetic layer 370 can have a thickness in the range of about 1 nm to about 5 nm.

FIG. 4 illustrates an embodiment of a memory cell as disclosed herein that includes a GMR spin valve. As seen in FIG. 4 such a memory cell includes a first electrode layer 410, a spin filter layer 420, a magnetic layer 430, a GMR spin valve forming structure 450 that includes a GMR nonmagnetic layer 460 and a GMR magnetic layer 470, and a second electrode layer 440. In this embodiment, the GMR spin valve forming structure 450 that includes a GMR nonmagnetic layer 460 and a GMR magnetic layer 470 in combination with the magnetic layer 430 function as a GMR span valve.

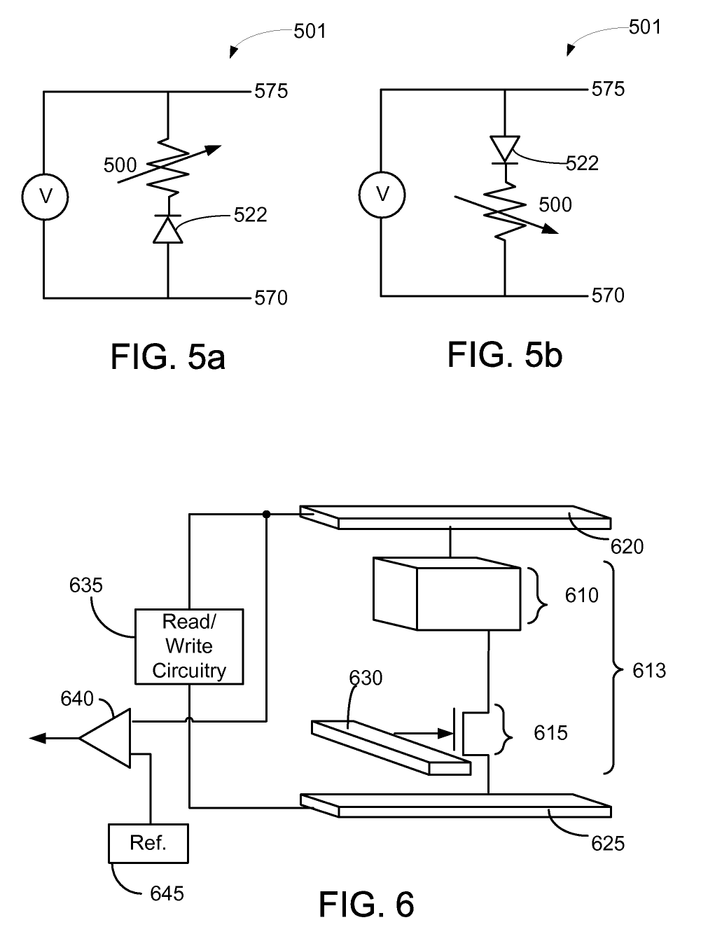

FIGS. 5a and 5b are schematic circuit diagrams of a memory device 501 that can be utilized with unipolar spin transfer switching. The memory device 501 includes a memory cell 500 as discussed above electrically coupled to a bit line 570 and a word line 575. The memory cell 500 is configured to switch between a high resistance state and a low resistance state by passing a voltage through the memory cell 500 in one direction or the other respectively. A transistor 522 is electrically coupled between the memory cell 500 and the word line 570. In other embodiments, the transistor 522 can be electrically coupled between the memory cell 500 and the bit line 575, as illustrated in FIG. 5b. A voltage source V provides the voltage across the memory cell 500 to read or write the high resistance state and the low resistance state.

In many embodiments, the voltage source V is a voltage pulse generator that is capable of generating a unipolar voltage pulse through the memory cell 500. In many embodiments, the voltage source V is a voltage pulse generator that is capable of generating a unipolar forward bias voltage pulse through the memory cell 500. The unipolar forward bias voltage pulse passes through the transistor 522 in only the forward bias direction of the transistor 522.

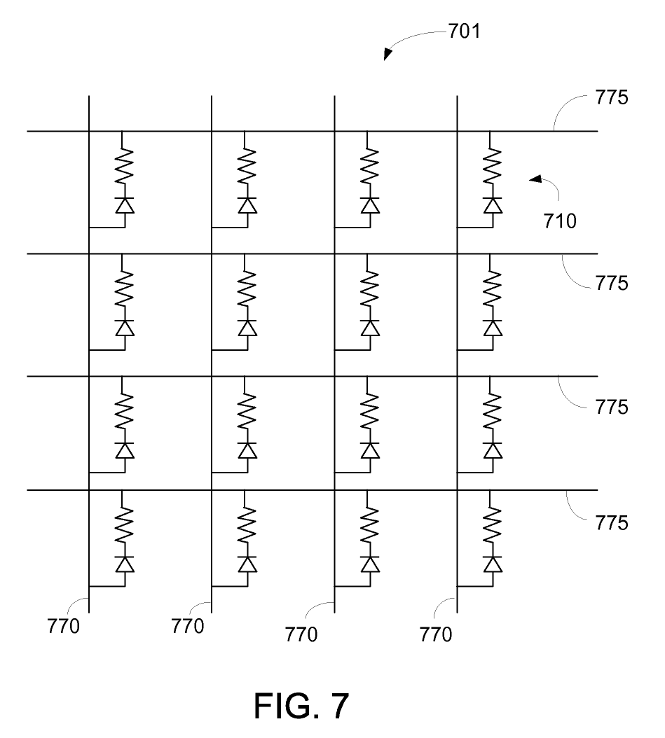

FIG. 6 illustrates a memory device 600 that includes a memory structure 613 that can include a memory cell 610 and its corresponding transistor 615. Each memory structure 613 is then configured within a larger system. The memory structure 613 is operatively coupled between a bit line 620 and a source line 625. The read/write circuitry 635 controls which bit line 620 and source line 625 that current is passed through to read or write. The read/write circuitry 635 can also control the voltage applied across the bit line 620 or memory structure 613 from the source line 625 (or vice versa). The direction which current flows across a memory cell 610 is determined by the voltage differential across the bit line 620 and the source line 625.

A particular memory cell 610 can be read from by activating its corresponding transistor 615, which when turned on, allows current to flow from the bit line 620 through the memory cell 610 to the source line 625 (or vice versa). The transistor 615 is activated and deactivated through the word line 630. The word line 630 is operatively coupled to and supplies a voltage to the transistor 615 to turn the transistor on so that current can flow to the memory cell 610. A voltage, dependent on the resistance of the memory cell 610 is then detected by the sense amplifier 640 from the source line 625 (for example). The voltage differential between the bit line 620 and the source line 625 (or vice versa), which is indicative of the resistance of the memory cell 610 is then compared to a reference voltage 645 and amplified by the sense amplifier 640 to determine whether the memory cell 610 contains a “1” or a “0”.

FIG. 7 is a schematic circuit diagram of an illustrative memory array 701. A plurality of memory devices 710 (that includes a memory cell and a transistor for example) can be arranged in an array to form the memory array 701. The memory array 701 includes a number of parallel conductive bit lines 775. The memory array 701 includes a number of parallel conductive word lines 770 that are generally orthogonal to the bit lines 775. The word lines 770 and bit lines 775 form a cross-point array where a memory device 710 is disposed at each cross-point. The memory device 710 and memory array 701 can be formed using conventional semiconductor fabrication techniques.

Thus, embodiments of ST-RAM EMPLOYING A SPIN FILTER are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present disclosure is limited only by the claims that follow.

What is claimed is:

1. A memory cell comprising:
a first electrode layer electrically connected to a control circuit;
a spin filter layer comprising a material that has exchange splitting in the conduction band; and
a magnetic layer, wherein a magnetization orientation of the magnetic layer can be effected by the torque of electrons tunneling through,
wherein the spin filter layer is between the first electrode layer and the magnetic layer.

2. The memory cell according to claim 1, wherein the spin filter layer comprises europium (Eu), selenium (Se), cobalt (Co), iron (Fe), bismuth (Bi), manganese (Mn), nickel (Ni) or combinations thereof.

3. The memory cell according to claim 2, wherein the spin filter layer comprises EuS, EuO, EuSe, CoFe₂O₄, BiMnO₃, or NiFe₂O₄.

4. The memory cell according to claim 2, wherein the spin filter layer has a thickness of about 2 nm to about 10 nm.

5. The memory cell according to claim 1 further comprising a second electrode layer on the magnetic layer.

6. The memory cell according to claim 5 further comprising a giant magnetoresistive (GMR) spin valve forming structure between the magnetic layer and the second electrode layer.

7. The memory cell according to claim 6, wherein the GMR spin valve forming structure comprises a GMR nonmagnetic layer and a GMR magnetic layer.

8. The memory cell according to claim 7, wherein the GMR nonmagnetic layer is positioned on the magnetic layer of the memory cell.

9. A memory device comprising:
a memory cell comprising:
a first electrode layer electrically connected to a control circuit;
a spin filter layer comprising a material that has exchange splitting in the conduction band; and
a magnetic layer, wherein a magnetization orientation of the magnetic layer can be effected by the torque of electrons tunneling through,
wherein the spin filter layer is between the first electrode layer and the magnetic layer; and
a transistor electrically connected to the memory cell.

10. The memory device according to claim 9, wherein the spin filter layer comprises europium (Eu), selenium (Se), cobalt (Co), iron (Fe), bismuth (Bi), manganese (Mn), nickel (Ni) or combinations thereof.

11. The memory device according to claim 10, wherein the spin filter layer comprises EuS, EuO, EuSe, CoFe₂O₄, BiMnO₃, or NiFe₂O₄.

12. The memory device according to claim 9, wherein the spin filter layer has a thickness of about 2 nm to about 10 nm.

13. The memory device according to claim 9, further comprising a second electrode layer on the magnetic layer.

14. The memory device according to claim 13, further comprising a giant magnetoresistive (GMR) spin valve forming structure between the magnetic layer and the second electrode layer.

15. A memory array comprising:
a plurality of memory structures, each of the plurality of memory structures comprising a memory cell, wherein the memory cell comprises:
a first electrode layer;
a spin filter layer comprising a material that has exchange splitting in the conduction band; and
a magnetic layer, wherein a magnetization orientation of the magnetic layer can be effected by the torque of electrons tunneling through,
wherein the spin filter layer is between the first electrode layer and the magnetic layer; and
a transistor, wherein the transistor is operatively coupled to the memory cell;
a plurality of bit lines; and
a plurality of source lines,
wherein each of the plurality of memory cells is operatively coupled between a bit line and a source line, the plurality of memory cells are arranged in a matrix and the bit lines and source lines connect the plurality of memory cells; and
a plurality of word lines;
wherein each of the plurality of transistors are operatively coupled to a word line.

16. The memory array according to claim 15, wherein the spin filter layer comprises europium (Eu), selenium (Se), cobalt (Co), iron (Fe), bismuth (Bi), manganese (Mn), nickel (Ni) or combinations thereof.

17. The memory array according to claim 15, wherein the spin filter layer comprises EuS, EuO, EuSe, CoFe₂O₄, BiMnO₃, or NiFe₂O₄.

18. The memory array according to claim 15, wherein the spin filter layer has a thickness of about 2 nm to about 10 nm.

19. The memory array according to claim 15 further comprising a second electrode layer adjacent to the magnetic layer and a giant magnetoresistive (GMR) spin valve forming structure between the magnetic layer and the second electrode layer.

20. The memory array according to claim 19, wherein the GMR spin valve forming structure comprises a GMR nonmagnetic layer and a GMR magnetic layer.
